(19) United States
(12) Patent Application Publication
(10) Pub. No.: US 2024/0223149 A1
(43) Pub. Date: Jul. 4, 2024

(54) METHOD OF FORMING ACOUSTIC WAVE DEVICE WITH SELECTIVELY ROUNDED INTERDIGITAL TRANSDUCER ELECTRODE

(71) Applicant: Skyworks Solutions, Inc., Irvine, CA (US)

(72) Inventors: Rei Goto, Osaka-Shi (JP); Tatsuya Fujii, Nagaokakyo-Shi (JP)

(21) Appl. No.: 18/530,618

(22) Filed: Dec. 6, 2023

Related U.S. Application Data
(60) Provisional application No. 63/477,792, filed on Dec. 29, 2022.
(60) Provisional application No. 63/477,775, filed on Dec. 29, 2022.
(60) Provisional application No. 63/477,783, filed on Dec. 29, 2022.

(51) Int. Cl. H03H 3/08; H03H 9/145; H03H 9/25

(52) U.S. Cl. CPC H03H 3/08; H03H 9/14538; H03H 9/25

(57) ABSTRACT

A method of forming an acoustic wave device is disclosed. The method can include providing a piezoelectric layer, forming an interdigital transducer electrode with the piezoelectric layer, and selectively removing at least a portion of the interdigital transducer electrode. The interdigital transducer electrode includes a finger extending from a bus bar. The finger has a first region and a second region between the first region and the bus bar. The finger has a lower side, an upper side opposite the lower side, a sidewall between the lower side and the upper side, and a corner between the upper side and the sidewall. Selectively removing at least a portion of the interdigital transducer electrode includes selectively removing at least a portion of the second region of the finger such that the corner in the second region of the finger has a more rounded corner than the corner in the first region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/477,792, filed Dec. 29, 2022, titled “ACOUSTIC WAVE DEVICE WITH PARTIALLY ROUNDED INTERDIGITAL TRANSDUCER ELECTRODE,” U.S. Provisional Patent Application No. 63/477,775, filed Dec. 29, 2022, titled “MULTILAYER PIEZOELECTRIC SUBSTRATE ACOUSTIC WAVE DEVICE WITH TRANSVERSE MODE SUPPRESSION,” and U.S. Provisional Patent Application No. 63/477,783, filed Dec. 29, 2022, titled “METHOD OF FORMING ACOUSTIC WAVE DEVICE WITH SELECTIVELY ROUNDED INTERDIGITAL TRANSDUCER ELECTRODE” are hereby incorporated by reference under 37 CFR 1.57 in their entirety.

### BACKGROUND

### Technical Field

Embodiments of this disclosure relate to acoustic wave devices.

### Description of Related Technology

A surface acoustic wave filter can include a plurality of surface acoustic wave resonators arranged to filter a radio frequency signal. Each resonator can include a surface acoustic wave device. Example piezoelectric MEMS resonators include surface acoustic (SAW) resonators and temperature compensated surface acoustic wave (TC-SAW) resonators. A surface acoustic wave device can be configured to generate, for example, a Rayleigh mode surface acoustic wave in which the main mode of the acoustic wave generated by the surface acoustic wave device is Rayleigh mode, or a shear horizontal mode surface acoustic wave in which the main mode of the acoustic wave generated by the surface acoustic wave device is shear horizontal mode.

Surface acoustic wave filters can be implemented in radio frequency electronic systems. For instance, filters in a radio frequency front end of a mobile phone can include surface acoustic wave filters. A plurality of acoustic wave filters can be arranged as a multiplexer. For example, two surface acoustic wave filters can be arranged as a duplexer. Transverse leakage generally degrades the performance of the surface acoustic wave device.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an acoustic wave device including: a piezoelectric layer; and an interdigital transducer electrode formed with the piezoelectric layer, the interdigital transducer electrode including a finger extending from a bus bar, the finger having a first region and a second region between the first region and the bus bar, the finger having a lower side, an upper side opposite the lower side, and a sidewall between the lower side and the upper side, a corner between the upper side and the sidewall is more rounded in the second region than in the first region.

In some embodiments, the techniques described herein relate to an acoustic wave device wherein the corner in the second region has a corner radius in a range of 0.01 L to 0.1 L where L is a wavelength generated by the acoustic wave device.

In some embodiments, the techniques described herein relate to an acoustic wave device wherein the corner radius is in a range of 0.03 L to 0.07 L.

In some embodiments, the techniques described herein relate to an acoustic wave device wherein the corner in the second region has a corner radius in of a range of 40 nm to 400 nm.

In some embodiments, the techniques described herein relate to an acoustic wave device wherein the corner in the second region has a corner radius in a range of 120 nm to 200 nm.

In some embodiments, the techniques described herein relate to an acoustic wave device wherein the corner in the first region has an edge.

In some embodiments, the techniques described herein relate to an acoustic wave device wherein the corner in the second region is curved and has no edge.

In some embodiments, the techniques described herein relate to an acoustic wave device wherein the finger has a third region between the second region and the bus bar, the corner in the second region is more rounded than in the third region.

In some embodiments, the techniques described herein relate to an acoustic wave device further including a support substrate below the piezoelectric layer such that the piezoelectric layer is positioned between the support substrate and the interdigital transducer electrode, an acoustic impedance of the support substrate is higher than an acoustic impedance of the piezoelectric layer.

In some embodiments, the techniques described herein relate to an acoustic wave device further including an intermediate layer between the support substrate and the piezoelectric layer.

In some embodiments, the techniques described herein relate to an acoustic wave device wherein the interdigital transducer electrode further includes a second bus bar and dummy fingers in a gap region between the bus bar and fingers that extend from the second bus bar.

In some aspects, the techniques described herein relate to an acoustic wave device including: a piezoelectric layer; and an interdigital transducer electrode formed with the piezoelectric layer, the interdigital transducer electrode including a first bus bar, a second bus bar, a first set of fingers extending from the first bus bar, and a second set of fingers extending from the second bus bar, the interdigital transducer electrode having a first gap region between the first set of fingers and the second bus bar, a second gap region between the second set of fingers and the first bus bar, and an active region between the first and second gap regions, the active region having a first border region, a second border region, and a center region between the first and second border regions, a finger of the first set of fingers having a lower side, an upper side opposite the lower side, and a sidewall between the lower side and the upper side, a corner between the upper side and the sidewall is more rounded in the center region than in the first border region.

In some embodiments, the techniques described herein relate to an acoustic wave device wherein the corner in the center region has a corner radius in a range of 0.01 L to 0.11 L where L is a wavelength generated by the acoustic wave device.

In some embodiments, the techniques described herein relate to an acoustic wave device wherein the corner radius is in a range of 0.03 L to 0.07 L.

In some embodiments, the techniques described herein relate to an acoustic wave device wherein the corner in the center region has a corner radius in of a range of 40 nm to 400 nm.

In some embodiments, the techniques described herein relate to an acoustic wave device wherein the corner in the second region has a corner radius in a range of 120 nm to 200 nm.

In some embodiments, the techniques described herein relate to an acoustic wave device wherein the corner in the border region has an edge.

In some embodiments, the techniques described herein relate to an acoustic wave device wherein the corner in the center region is curved and has no edge.

In some embodiments, the techniques described herein relate to an acoustic wave device wherein the corner in the center region is more rounded than in the second border region.

In some embodiments, the techniques described herein relate to an acoustic wave device further including a support substrate below the piezoelectric layer such that the piezoelectric layer is positioned between the support substrate and the interdigital transducer electrode, an acoustic impedance of the support substrate is higher than an acoustic impedance of the piezoelectric layer.

In some embodiments, the techniques described herein relate to an acoustic wave device further including an intermediate layer between the support substrate and the piezoelectric layer.

In some aspects, the techniques described herein relate to an acoustic wave device including: a piezoelectric layer; and an interdigital transducer electrode formed with the piezoelectric layer, the interdigital transducer electrode including a finger extending from a bus bar, the finger having a first region and a second region between the first region and the bus bar, the finger having a lower side and an upper side opposite the lower side, the lower side being closer to the piezoelectric layer than the upper side, widths of the lower side in the first and second regions are generally the same, and a width of the upper side in the first region is greater than a width of the upper side in the second region.

In some embodiments, the techniques described herein relate to an acoustic wave device wherein a width of the lower side in the second region is greater than the width of the upper side in the second region.

In some embodiments, the techniques described herein relate to an acoustic wave device wherein a difference between the widths of the lower side and the upper side in the second region is in a range of 0.02 L to 0.2 L where L is a wavelength generated by the acoustic wave device.

In some embodiments, the techniques described herein relate to an acoustic wave device wherein the difference between the widths of the lower side and the upper side in the second region is in a range of 0.06 L to 0.1 L.

In some embodiments, the techniques described herein relate to an acoustic wave device wherein a difference between the widths of the lower side and the upper side in the second region is in a range of 80 nm to 800 nm.

In some embodiments, the techniques described herein relate to an acoustic wave device wherein a difference between the width of the upper side in the first region and the width of the upper side in the second region is in a range of 0.02 L to 0.2 L where L is a wavelength generated by the acoustic wave device.

In some embodiments, the techniques described herein relate to an acoustic wave device wherein the difference between the width of the upper side in the first region and the width of the upper side in the second region is in a range of 0.06 L to 0.1 L.

In some embodiments, the techniques described herein relate to an acoustic wave device wherein a difference between the width of the upper side in the first region and the width of the upper side in the second region is in a range of 80 nm to 800 nm.

In some embodiments, the techniques described herein relate to an acoustic wave device wherein the finger further has a sidewall between the lower side and the upper side, a corner between the upper side and the sidewall in the first region has an edge and the corner in the second region has a curvature.

In some embodiments, the techniques described herein relate to an acoustic wave device further including a support substrate below the piezoelectric layer such that the piezoelectric layer is positioned between the support substrate and the interdigital transducer electrode, and an intermediate layer between the support substrate and the piezoelectric layer, an acoustic impedance of the support substrate is higher than an acoustic impedance of the piezoelectric layer.

In some embodiments, the techniques described herein relate to an acoustic wave device wherein the interdigital transducer electrode further includes a second bus bar and dummy fingers in a gap region between the bus bar and fingers that extend from the second bus bar.

In some aspects, the techniques described herein relate to an acoustic wave device including: a piezoelectric layer; and an interdigital transducer electrode formed with the piezoelectric layer, the interdigital transducer electrode including a first bus bar, a second bus bar, a first set of fingers extending from the first bus bar, and a second set of fingers extending from the second bus bar, the interdigital transducer electrode having a first gap region between the first set of fingers and the second bus bar, a second gap region between the second set of fingers and the first bus bar, and an active region between the first and second gap regions, the active region having a first border region, a second border region, and a center region between the first and second border regions, a finger of the first set of fingers having a lower side and an upper side opposite the lower side, widths of the lower side in the first and second border regions are generally the same, and a width of the upper side in the first border region is greater than a width of the upper side in the center region.

In some embodiments, the techniques described herein relate to an acoustic wave device wherein a width of the lower side in the center region is greater than the width of the upper side in the center region.

In some embodiments, the techniques described herein relate to an acoustic wave device wherein a difference between the widths of the lower side and the upper side in the center region is in a range of 0.02 L to 0.2 L where L is a wavelength generated by the acoustic wave device.

In some embodiments, the techniques described herein relate to an acoustic wave device wherein the difference between the widths of the lower side and the upper side in the center region is in a range of 0.06 L to 0.1 L.

In some embodiments, the techniques described herein relate to an acoustic wave device wherein a difference between the widths of the lower side and the upper side in the center region is in a range of 80 nm to 800 nm.

In some embodiments, the techniques described herein relate to an acoustic wave device wherein a difference between the width of the upper side in the first border region and the width of the upper side in the center region is in a range of 0.02 L to 0.2 L where L is a wavelength generated by the acoustic wave device.

In some embodiments, the techniques described herein relate to an acoustic wave device a width of the upper side in the second border region is greater than the width of the upper side in the center region.

In some embodiments, the techniques described herein relate to an acoustic wave device wherein a difference between the width of the upper side in the first border region and the width of the upper side in the center region is in a range of 80 nm to 800 nm.

In some embodiments, the techniques described herein relate to an acoustic wave device wherein the finger further has a sidewall between the lower side and the upper side, a corner between the upper side and the sidewall in the first border region has an edge and the corner in the center region has a curvature.

In some embodiments, the techniques described herein relate to an acoustic wave device further including a support substrate below the piezoelectric layer such that the piezoelectric layer is positioned between the support substrate and the interdigital transducer electrode, and an intermediate layer between the support substrate and the piezoelectric layer, an acoustic impedance of the support substrate is higher than an acoustic impedance of the piezoelectric layer.

In some aspects, the techniques described herein relate to a method of forming an acoustic wave device, the method including: providing a piezoelectric layer; forming an interdigital transducer electrode with the piezoelectric layer, the interdigital transducer electrode including a finger extending from a bus bar, the finger having a first region and a second region between the first region and the bus bar, the finger having a lower side, an upper side opposite the lower side, a sidewall between the lower side and the upper side, and a corner between the upper side and the sidewall; and selectively removing at least a portion of the second region of the finger such that the corner in the second region of the finger has a more rounded corner than the corner in the first region.

In some embodiments, the techniques described herein relate to a method wherein selectively removing includes ashing.

In some embodiments, the techniques described herein relate to a method wherein selectively removing includes ion beam trimming.

In some embodiments, the techniques described herein relate to a method wherein selectively removing includes dry etching.

In some embodiments, the techniques described herein relate to a method wherein selectively removing includes wet etching.

In some embodiments, the techniques described herein relate to an acoustic wave device a corner radius is in a range of 0.03 L to 0.07 L where L is a wavelength generated by the acoustic wave device.

In some embodiments, the techniques described herein relate to an acoustic wave device wherein the corner in the second region has a corner radius in a range of 120 nm to 200 nm.

In some embodiments, the techniques described herein relate to an acoustic wave device wherein selectively removing includes removing an edge from the corner in the second region.

In some embodiments, the techniques described herein relate to an acoustic wave device wherein selectively removing includes narrowing a width of the upper side in the second region while maintaining a width of the lower side in the second region.

In some embodiments, the techniques described herein relate to a method wherein the interdigital transducer electrode is formed on the piezoelectric layer.

In some embodiments, the techniques described herein relate to an acoustic wave device wherein the interdigital transducer electrode further includes a second bus bar and dummy fingers in a gap region between the bus bar and fingers that extend from the second bus bar.

In some aspects, the techniques described herein relate to a method of forming an acoustic wave device, the method including: providing a piezoelectric layer; forming an interdigital transducer electrode with the piezoelectric layer, the interdigital transducer electrode including a finger extending from a bus bar, the finger having a first region and a second region between the first region and the bus bar, the finger having a lower side, an upper side opposite the lower side, a sidewall between the lower side and the upper side, and a corner between the upper side and the sidewall; and selectively removing at least a portion of the second region of the finger such that a width of the upper side in the first region of the finger is greater than a width of the upper side in the second region of the finger.

In some embodiments, the techniques described herein relate to a method wherein selectively removing includes ashing.

In some embodiments, the techniques described herein relate to a method wherein selectively removing includes ion beam trimming.

In some embodiments, the techniques described herein relate to a method wherein selectively removing includes etching.

In some embodiments, the techniques described herein relate to a method wherein a width of the lower side in the first region is greater than the width of the upper side in the second region.

In some embodiments, the techniques described herein relate to a method wherein a difference between the widths of the lower side and the upper side in the second region is in a range of 0.06 L to 0.1 L where L is a wavelength generated by the acoustic wave device.

In some embodiments, the techniques described herein relate to a method wherein a difference between the width of the upper side in the first region and the width of the upper side in the second region is in a range of 0.06 L to 0.1 L where L is a wavelength generated by the acoustic wave device.

In some embodiments, the techniques described herein relate to a method wherein a difference between the width of the upper side in the first region and the width of the upper side in the second region is in a range of 80 nm to 800 nm.

In some embodiments, the techniques described herein relate to a method wherein selectively removing includes narrowing a width of the upper side in the second region while maintaining a width of the lower side in the second region.

In some embodiments, the techniques described herein relate to a method wherein the interdigital transducer electrode is formed on the piezoelectric layer.

For purposes of summarizing the disclosure, certain aspects, certain embodiments, advantages, and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

The present disclosure relates to U.S. patent application Ser. No. [Attorney Docket SKYWRKS.1390A1], titled “ACOUSTIC WAVE DEVICE WITH PARTIALLY ROUNDED INTERDIGITAL TRANSDUCER ELECTRODE,” filed on even date herewith, and U.S. patent application Ser. No. [Attorney Docket SKYWRKS.1390A2], titled “MULTILAYER PIEZOELECTRIC SUBSTRATE ACOUSTIC WAVE DEVICE WITH TRANSVERSE MODE SUPPRESSION,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic top plan view of a surface acoustic wave (SAW) device according to an embodiment.

FIGS. 1B, 1C, 1D, and 1E are schematic cross-sectional side views of the SAW device of FIG. 1A taken along different locations.

FIG. 1F is an enlarged view of a finger in a border region BR of the SAW device of FIGS. 1A-1E.

FIG. 1G is an enlarged view of the finger in a center region CR of the SAW device of FIGS. 1A-1E.

FIGS. 2A to 2G show various example shapes of an interdigital (IDT) transducer electrode.

FIG. 3A is a graph showing velocity variations of acoustic velocities simulated using different IDT profiles.

FIG. 3B is shows a baseline profile of the IDT electrode having a rectangle shape.

FIG. 3C is shows a baseline profile of the IDT electrode having reduced portions relative to the baseline profile.

FIGS. 4A and 4B are graphs showing simulation results of admittance of the SAW device having the rectangle IDT electrode shape shown in FIG. 3B and admittance of the SAW device having the IDT electrode with reduced portions shown in FIG. 3C.

FIGS. 5A and 5B are graphs showing simulation results of admittance of the SAW devices having the IDT electrode with reduced portions shown in FIG. 3C with different corner radii.

FIG. 5C is a graph showing a relationship between the duty factor DF and a capacitance per area normalized by a capacitance per area when DF is 0.5.

FIG. 6A is a schematic top plan view of a surface acoustic wave (SAW) device according to an embodiment.

FIGS. 6B and 6C are schematic cross-sectional side views of the SAW device of FIG. 6A taken along different locations.

FIG. 7A is a schematic diagram of a ladder filter that includes an acoustic wave resonator according to an embodiment.

FIG. 7B is a schematic diagram of a transmit filter that includes a surface acoustic wave resonator according to an embodiment.

FIG. 7C is a schematic diagram of a receive filter that includes a surface acoustic wave resonator according to an embodiment.

FIG. 8 is a schematic diagram of a radio frequency module that includes a surface acoustic wave component according to an embodiment.

FIG. 9 is a schematic diagram of a radio frequency module that includes filters with surface acoustic wave resonators according to an embodiment.

FIG. 10A is a schematic block diagram of a wireless communication device that includes a filter in accordance with one or more embodiments.

FIG. 10B is a schematic block diagram of another wireless communication device that includes a filter in accordance with one or more embodiments.

FIG. 11 is a schematic block diagram of a wireless communication device that includes a filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. The surface acoustic wave devices include, for example, SAW resonators, SAW delay lines, and multi-mode SAW (MMS) filters (e.g., double mode SAW (DMS) filters).

In general, high quality factor (Q), large effective electromechanical coupling coefficient or coupling factor (K²), high frequency ability, and spurious free can be significant aspects for micro resonators to enable low-loss filters, stable oscillators, and sensitive sensors. SAW devices can have a relatively strong transverse mode in and/or near a pass band. The presence of the relatively strong transverse modes can hinder the accuracy and/or stability of oscillators and sensors, as well as hurt the performance of acoustic wave filters by, for example, creating relatively severe passband ripples and possibly limiting the rejection.

Therefore, transverse mode suppression is significant for SAW resonators. A technical solution for suppressing transverse modes is to create a border region with a different frequency from a center region of the active region according to the mode dispersion characteristic. This can be referred to as a “piston mode.” A piston mode can be obtained to cancel out the transverse wave vector in a lateral direction without significantly degrading the k² or Q. By including a relatively small border region with a slower velocity on the edge of the acoustic aperture of a SAW resonator, a propagating mode can have a zero (or approximately zero) transverse wave vector in the active aperture.

One way of achieving piston mode is to include a material that can cause a magnitude of the velocity in the underlying region of the SAW resonator to be increased. The material can be, for example, silicon nitride (SiN). As an example, a SiN layer can be positioned over a center region of an interdigital transducer electrode (IDT) and the border region of the IDT can be free from the SiN. Another way to achieve piston mode is to provide a mass loading strip (e.g., a conductive strip) on edges of an IDT electrode active regions of the SAW resonator. The transverse wave vector can be real in the border region and imaginary on a gap region. However, these structures can make the acoustic wave device structurally more complicated due to the additional elements (e.g., the SiN layer and/or the mass loading strip).

Various embodiments disclosed herein relate to acoustic wave devices with a partially, selectively rounded or reduced interdigital transducer (IDT) electrode. An acoustic wave device can include a piezoelectric layer and an interdigital transducer electrode formed with the piezoelectric layer. The interdigital transducer electrode includes a finger extending from a bus bar. The finger has a first region and a second region between the first region and the bus bar. The finger has a lower side, an upper side opposite the lower side, and a sidewall between the lower side and the upper side. A corner between the upper side and the sidewall is more rounded in the second region than in the first region. The rounded corner in the second region can contribute to transverse mode suppression without the additional elements (e.g., the SiN layer and/or the mass loading strip).

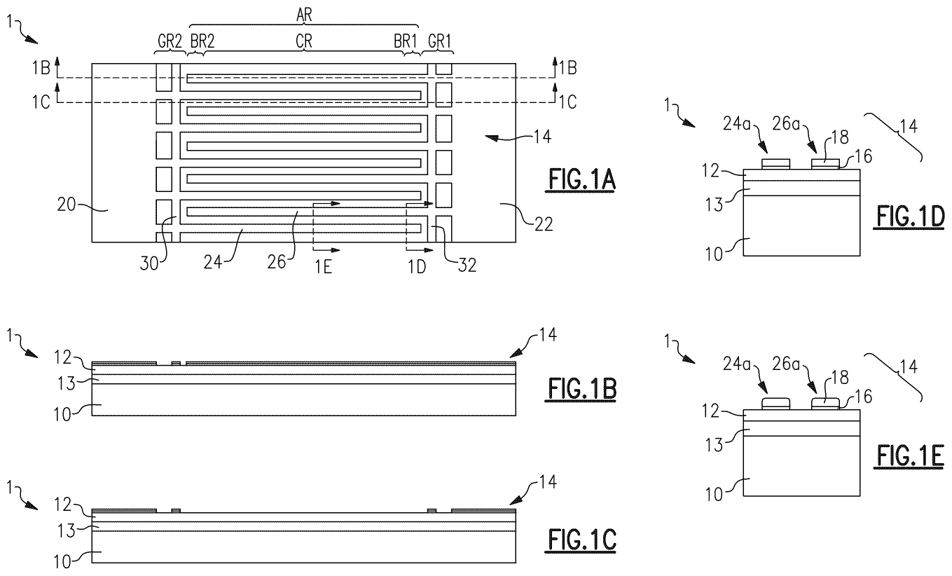

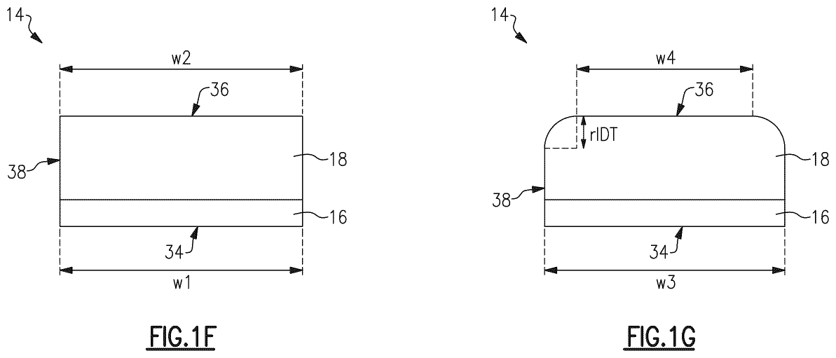

FIG. 1A is a schematic top plan view of a surface acoustic wave (SAW) device 1 according to an embodiment. FIGS. 1B, 1C, 1D, and 1E are schematic cross-sectional side views of the SAW device 1 of FIG. 1A taken along different locations. The SAW device 1 can include a support substrate 10, a piezoelectric layer 12, an intermediate layer 13 between the support substrate 10 and the piezoelectric layer 12, and an interdigital transducer (IDT) electrode 14 formed with the piezoelectric layer 12. In the illustrated embodiment, the IDT electrode 14 is formed over the piezoelectric layer 12. The SAW device 1 shown in FIG. 1A-1E is a multilayer piezoelectric substrata (MPS) SAW device. However, the principles and advantages disclosed herein may be implemented in any SAW device, such as, a temperature compensated surface acoustic wave (TC-SAW) device.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high acoustic impedance. An acoustic impedance of the support substrate 10 can be higher than an acoustic impedance of the piezoelectric layer 12. For instance, the support substrate 10 can have a higher acoustic impedance than an acoustic impedance of lithium niobate and a higher acoustic impedance than lithium tantalate. The acoustic impedance of the support substrate 10 can be higher than an acoustic impedance of silicon dioxide (SiO₂). The SAW resonator 1 including the piezoelectric layer 12 on a support substrate 10 with relatively high thermal conductivity, such as silicon substrate, can achieve better thermal dissipation compared to a similar SAW resonator without the high impedance support substrate 10.

The piezoelectric layer 12 can be a lithium tantalate (LT) layer. For example, the piezoelectric layer 12 can be an LT layer having a cut angle of 42° (42° Y-cut X-propagation LT) or a cut angle of 60° (60° Y-cut X-propagation LT). For example, the piezoelectric layer 12 can be 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 12. A thickness of the piezoelectric layer 12 can be selected based on a wavelength A or L of a surface acoustic wave generated by the SAW device 1 in certain applications. The IDT electrode 14 has a pitch that sets the wavelength A or L of the SAW device 1. The piezoelectric layer 12 can be sufficiently thick to avoid significant frequency variation.

In some embodiments, the intermediate layer 13 can act as an adhesive layer. The intermediate layer 13 can include any suitable material. The intermediate layer 13 can be, for example, an oxide layer (e.g., a silicon dioxide (SiO₂) layer).

The illustrated IDT electrode 14 can include a first layer 16 and a second layer 18. The IDT electrode 12 includes first bus bar 20, a second bus bar 22, a first set of fingers 24 that extends from the first bus bar, and a second set of fingers 26 that extends from the second bus bar. The first set of fingers 24 includes a first finger 24a and the second set of fingers 26 includes a second finger 26a. In the SAW device 1, the IDT electrode 14 includes separate IDT layers (e.g., the first layer 16 and the second layer 18) that impact acoustic properties and electrical properties. Accordingly, in some embodiments, electrical properties, such as insertion loss, can be improved by adjusting one of the IDT layers without significantly impacting acoustic properties.

The first layer 16 of the IDT electrode 14 can be referred to as a lower electrode layer. The first layer 16 of the IDT electrode 14 is disposed between the second layer 16 of the IDT electrode 14 and the piezoelectric layer 12. As illustrated, the first layer 16 of the IDT electrode 14 can have a first side in physical contact with the piezoelectric layer 12 and a second side in physical contact with the second layer 18 of the IDT electrode 14. The second layer 18 of the IDT electrode 14 can be referred to as an upper electrode layer. The second layer 18 of the IDT electrode 14 can be disposed over the first layer 16 of the IDT electrode 14. As illustrated, the second layer 18 of the IDT electrode 14 can have a first side in physical contact with the first layer 16 of the IDT electrode 14. In some other embodiments, the first layer 16 and the second layer 18 can be switched.

The IDT electrode 14 can include any suitable material. For example, the first layer 16 can be tungsten (W) and the second layer 18 can be aluminum (Al) in certain embodiments. The IDT electrode 14 may include one or more other metals, such as copper (Cu), Magnesium (Mg), titanium (Ti), molybdenum (Mo), etc. The IDT electrode 14 may include alloys, such as AlMgCu, AlCu, etc. In some embodiments, a thickness of the first layer 16 can be in a range from 0.01 L to 0.075 L and a thickness of the second layer 18 can be in a range from 0.05 L to 0.2 L. For example, when the wavelength L is 4 μm, the thickness of the first layer 16 can be about 40 nm to 300 nm and the thickness of the second layer 18 can be about 200 nm to 800 nm. Although the IDT electrode 14 has a dual-layer structure in the illustrated embodiments, any suitable principles and advantages disclosed herein can be applied to single layer IDT electrodes or multi-layer IDT electrodes that include three or more IDT layers.

The IDT electrode 14 can include a first gap region GR1 between the first set of fingers 24 and the second bus bar 22, a second gap region GR2 between the second set of fingers 26 and the first bus bar 20, and an active region AR between the first and second gap regions GR1, GR2. In some embodiments, the IDT electrode 14 can include a first mini-bus bar 30 in the second gap region GR2 and a second mini-bus bar 32 in the first gap region GR1. The active region AR includes a center region CR, a first border region BR1 between the center region CR and the first gap region GR1, and a second border region BR2 between the center region CR and the second gap region GR2. The first and second border regions BR1, BR2 can be regions within 0.5 L, 1 L, or 1.5 L of the first and second sets of fingers 24, 26 from respective edges of the first and second sets of fingers 24, 26 or from the respective first or second gap regions GR1, GR2.

FIGS. 1D and 1E show the first finger 24a of the first set of fingers 24 and the second fingers 26a of the second set of fingers 26. The first finger 24a and the second finger 26a may have the same or generally similar structures. The other fingers of the first and second sets of fingers 24, 26 may include the same as or generally similar structures as the first and second fingers 24a, 26a.

FIG. 1F is an enlarged view of a finger (e.g., the first finger 24a or the second finger 26a) of the IDT electrode 14 in the border region BR (e.g., the first or second border region BR1, BR2). FIG. 1G is an enlarged view of the finger of the IDT electrode 14 in the center region CR. The IDT electrode 14 has a lower side 34, an upper side 36 opposite the lower side 34, and a sidewall 38 between the lower side 34 and the upper side 36.

The lower side 34 of the IDT electrode 14 in the border region BR has a width w1, the upper side 36 of the IDT electrode 14 in the border region BR has a width w2, the lower side 34 of the IDT electrode 14 in the center region CR has a width w3, the upper side 36 of the IDT electrode 14 in the center region CR has a width w4. The width w1 of the lower side 34 of the IDT electrode 14 in the border region BR, the width w2 of the upper side 36 of the IDT electrode 14 in the border region BR, and width w3 of the lower side 34 of the IDT electrode 14 in the center region CR can be generally similar. The width w4 of the upper side 36 of the IDT electrode 14 in the center region CR can be smaller than the width w1 of the lower side 34 of the IDT electrode 14 in the border region BR, the width w2 of the upper side 36 of the IDT electrode 14 in the border region BR, and width w3 of the lower side 34 of the IDT electrode 14 in the center region CR. For example, a difference between the width w1 and the width w2 can be less than 0.01 L, less than 0.005 L, or less than 0.001 L, or less than 40 nm, less than 20 nm, or less than 10 nm. For example, a difference between the width w1 and the width w3 can be less than 0.01 L, less than 0.005 L, or less than 0.001 L, or less than 40 nm, less than 20 nm, or less than 10 nm. In some embodiments, a difference between the width w3 and the width w4 can be in a range of 0.02 L to 0.2 L, 0.04 L to 0.2 L, 0.06 L to 0.2 L, 0.04 L to 0.1 L, or 0.06 L to 0.1 L, or in a range of 80 nm to 800 nm, 160 nm to 800 nm, 240 nm to 800 nm, 160 nm to 400 nm, or 240 nm to 400 nm. Similarly, in some embodiments, a difference between the width w2 and the width w4 can be in a range of 0.02 L to 0.2 L, 0.04 L to 0.2 L, 0.06 L to 0.2 L, 0.04 L to 0.1 L, or 0.06 L to 0.1 L, or in a range of 80 nm to 800 nm, 160 nm to 800 nm, 240 nm to 800 nm, 160 nm to 400 nm, or 240 nm to 400 nm.

In some embodiments, a corner between the upper side 36 and the sidewall 38 in the border region BR can have an edge (e.g., a sharp edge having an acute angle). In some embodiments, a corner between the upper side 36 and the sidewall 38 in the center region CR can be more rounded than the corner in the border region BR. In some embodiments, the corner in the center region CR can have a curved corner and no edge. In some embodiments, the corner in the center region CR can have a corner radius rIDT in a range of 0.01 L to 0.1 L, 0.02 L to 0.1 L, 0.03 L to 0.1 L, 0.03 L to 0.07 L, 0.02 L to 0.05 L, or 0.03 L to 0.05 L, or in a range of 40 nm to 400 nm, 80 nm to 400 nm, 120 nm to 400 nm, 80 nm to 200 nm, or 120 nm to 200 nm.

A corner profile of the IDT electrode 14 in the first and second gap regions GR1, GR2 can be similar to the corner profile of the IDT electrode 14 in the border region BR. However, in some other embodiments, the corner profile of the IDT electrode 14 in the first and second gap regions GR1, GR2 can be similar to the corner profile of the IDT electrode 14 in the center region CR.

The IDT electrode 14 with the rounded corner in the center region CR can be formed in any suitable manner. For example, the IDT electrode material(s) can be provided (e.g., deposited) over the piezoelectric layer 12, and at least a portion of the IDT electrode material(s) can be selectively removed. In some embodiments, the IDT electrode material(s) in the center region CR can be partially removed by way of, for example, ashing, ion beam trimming, dry etching, or wet etching to thereby form rounded corners. For example, the IDT electrode material(s) in the center region CR can be partially removed by way of O₂/N₂ ashing under a pressure (e.g., about 1 Pa) using a radio frequency (RF) power (e.g., about 500 W) with a bias power (e.g., about 120 W) for a duration (e.g., about 3 minutes). The intensity and/or the duration of the removal process can relate to the amount of the IDT being removed. Also, longer the duration can provide a smaller the taper angle or a greater corner radius rIDT. For example, when the IDT is processed with the O₂/N₂ ashing for 30 min, the taper angle can be about 45° in some embodiments. During the removal procedure, the border region BR can be covered by a protective layer. When the IDT electrode material(s) is/are provided, the center region CR and the border region BR can have the same or generally similar shapes. The removal procedure can remove at least a portion of the center region CR such that no portion of the border region BR is removed. Therefore, the IDT electrode 14 in the center region CR can at least partially have a signature of a removal process (e.g., ashing, ion beam trimming, dry etching, or wet etching), and the IDT electrode 14 in the border region BR can at least partially have a signature of the providing process (e.g., the deposition process).

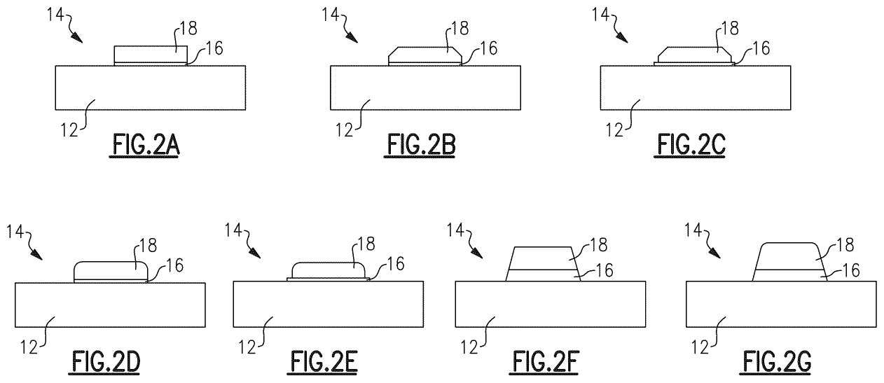

FIGS. 2A to 2G show various example shapes that the IDT electrode 14 can have. FIG. 2A shows a schematic cross-sectional side view of the IDT electrode 14 having a rectangle shape. FIG. 2B shows a schematic cross-sectional side view of the IDT electrode 14 having a tapered portion in the second layer 18. FIG. 2C shows a schematic cross-sectional side view of the IDT electrode 14 having a wider first layer 16 and a tapered portion in the second layer 18. FIG. 2D shows a schematic cross-sectional side view of the IDT electrode 14 having rounded corners. FIG. 2E shows a schematic cross-sectional side view of the IDT electrode 14 having rounded corners and a wider first layer 16. FIG. 2F shows a schematic cross-sectional side view of the IDT electrode 14 having tapered sidewalls. FIG. 2G shows a schematic cross-sectional side view of the IDT electrode 14 having tapered sidewalls with rounded corners. Any suitable combination of two or more shapes shown in FIGS. 2A-2G can be implemented for the IDT electrode 14 in the center region CR and the border region BR. For example, the IDT electrode 14 can have the shape shown in FIG. 2A in the border region BR, and the IDT electrode 14 can have the shape shown in FIG. 2B, 2D, 2F, or 2G in the center region CR. For example, the IDT electrode 14 can have the shape shown in FIG. 2B in the border region BR, and the IDT electrode 14 can have the shape shown in FIG. 2D, 2F, or 2G in the center region CR. For example, the IDT electrode 14 can have the shape shown in FIG. 2C in the border region BR, and the IDT electrode 14 can have the shape shown in FIG. 2E in the center region CR. For example, the IDT electrode 14 can have the shape shown in FIG. 2F in the border region BR, and the IDT electrode 14 can have the shape shown in FIG. 2G in the center region CR. In some embodiments, having the wider first layer 16 can increase the static capacitance and be beneficial for size reduction.

The difference(s) in shape and/or profile of the IDT electrode 14 between the center region CR and the border region BR as disclosed herein can provide an acoustic velocity difference between the center region CR and the border region BR, thereby enabling a piston mode operation and transverse mode suppression.

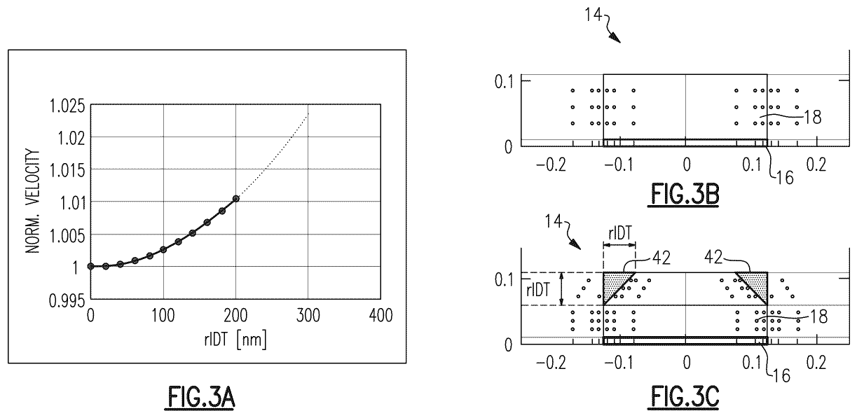

FIG. 3A is a graph showing velocity variations of acoustic velocities simulated using different IDT profiles. FIG. 3B shows a baseline profile of the IDT electrode 14 having a rectangle shape. FIG. 3C shows a baseline profile of the IDT electrode 14 having reduced portions 42 relative to the baseline profile. In the simulations, a SAW device similar to the SAW device 1 shown in FIGS. 1A-1E is used. A 40 nm thick molybdenum (Mo) layer is used as the first layer 16 of the IDT electrode 14, and a 400 nm thick aluminum (Al) layer is used as the second layer 18 of the IDT electrode 14. A pitch between adjacent fingers is set to 2 μm and the wavelength L is set to 4 μm. A 1 μm thick 42° Y-cut X-propagation LT is used as the piezoelectric layer 12, a 1 μm thick SiO₂ layer is used as the intermediate layer 13, and a silicon layer is used as the support substrate 10. A width of the lower side 34 of the IDT electrode 14 is set to 1 μm and kept consistent. In the baseline profile of the IDT electrode 14, a width of the upper side 36 is set to 1 μm. In FIG. 3C, upper corners are reduced by a corner radius rIDT relative to the baseline structure. The corner radius rIDT refers to two equal sides of isosceles triangle that is being reduced from the corners of the IDT electrode 14. The graph of FIG. 3A shows simulation results of rIDT=0 to rIDT=300 nm.

The simulation results indicate that the IDT electrode 14 having the reduced portions 42 increases the acoustic velocity relative to the baseline profile. As the size of the reduced portions increases, the acoustic velocity increases. For example, when the corner radius rIDT is 200 nm, the acoustic velocity is about 1.01 times the acoustic velocity of the baseline profile, and when the corner radius rIDT is 300 nm, the acoustic velocity is about 1.025 times the acoustic velocity of the baseline profile.

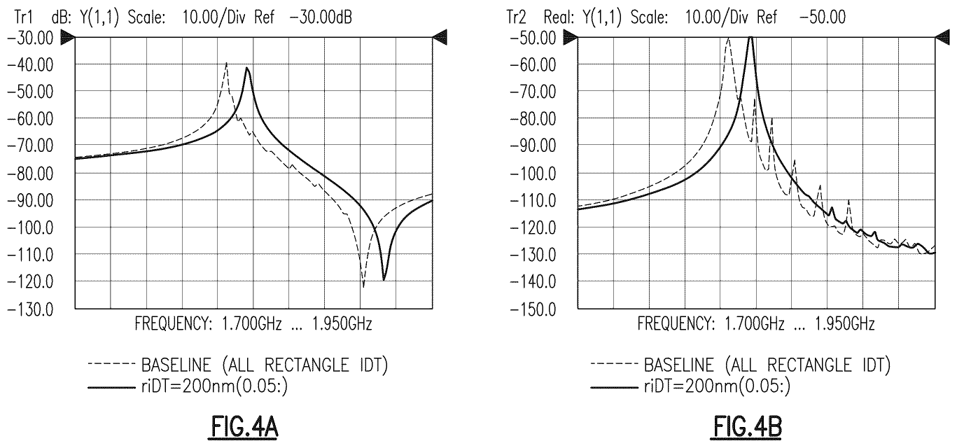

FIGS. 4A and 4B are graphs showing simulation results of admittance of the SAW device having the rectangle IDT electrode shape shown in FIG. 3B and admittance of the SAW device having the IDT electrode 14 with reduced portions 42 shown in FIG. 3C. The reduced portions 42 of the IDT electrode 14 used in the simulation have a corner radius rHDT of 200 nm or 0.05 L. FIG. 4A is a plot of dB(|Y|). FIG. 4B is a plot of dB(real{Y}). In the simulations of FIGS. 4A and 4B, a duty factor DF is set to 0.6. The duty factor DF is calculated as: DF=W/(λ/2), wherein W is the width of each finger of the IDT electrode 14, and λ is the pitch. In FIG. 4B, the transverse mode response is more pronounced than in FIG. 4A. The simulation results indicate that the reduced portions 42 can contribute to transverse mode suppression while keeping the DF of 0.6.

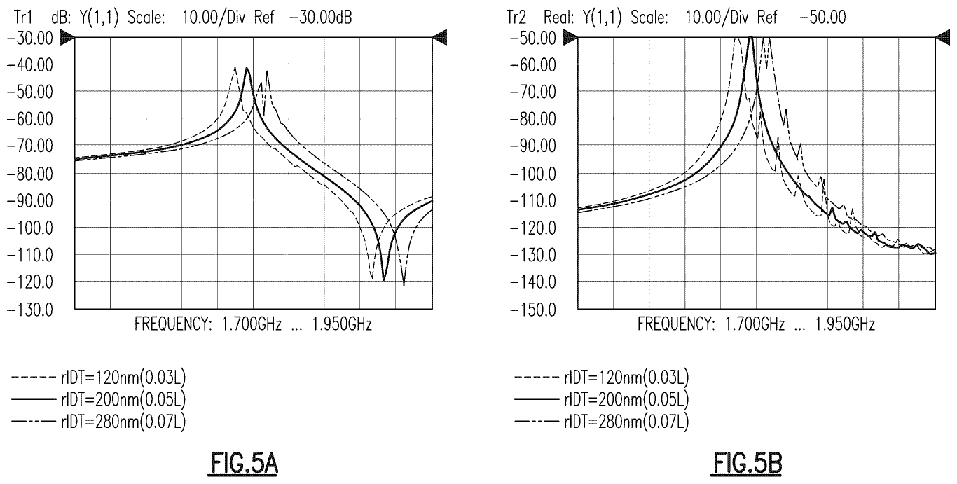

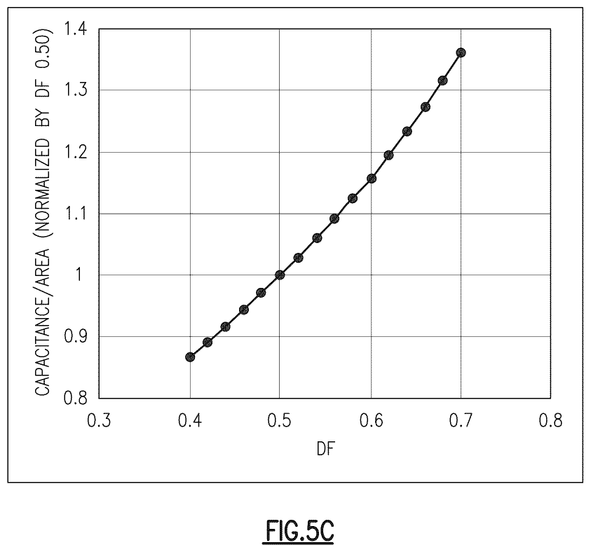

FIGS. 5A and 5B are graphs showing simulation results of admittance of the SAW devices having the IDT electrode 14 with reduced portions 42 shown in FIG. 3C with different corner radii rIDT of 120 nm or 0.03 L, 200 nm or 0.05 L, and 280 nm or 0.07 L. FIG. 5A is a plot of dB(|Y|). FIG. 5B is a plot of dB(real{Y}). In the simulations of FIGS. 5A and 5B, a duty factor DF is set to 0.6, and the border region BR width is set to 1 L. In FIG. 5B, the transverse mode response is more pronounced than in FIG. 5A. The simulation results indicate that when the corner radius is 200 nm or 0.05 L, the transverse mode is suppressed the most.

FIG. 5C is a graph showing a relationship between the duty factor DF and a capacitance per area normalized by a capacitance per area when DF is 0.5. As disclosed herein, the rounded or reduced IDT electrode can provide sufficient transverse mode suppression while maintaining the DF. Therefore, an increased static capacitance can be obtained by having a wider lower side IDT width, which, in turn, can contribute to size reduction of the SAW device. Without the rounded or reduced IDT electrode disclosed herein, a sufficient capacitance per area with a sufficiently clean response is obtained with the DF of about 0.4 to 0.48. However, with the rounded or reduced IDT electrode disclosed herein, a sufficient capacitance per area can be obtained with the DF of about 0.5 to 0.7. Thus, the embodiments disclosed herein can contribute to providing transverse mode suppression and size reduction.

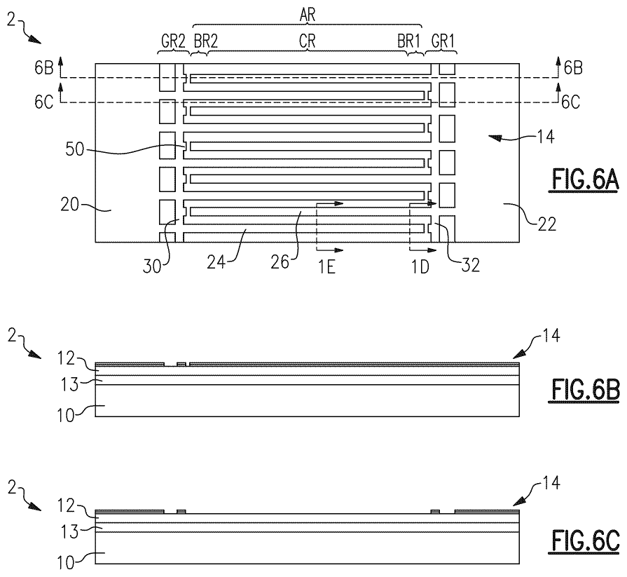

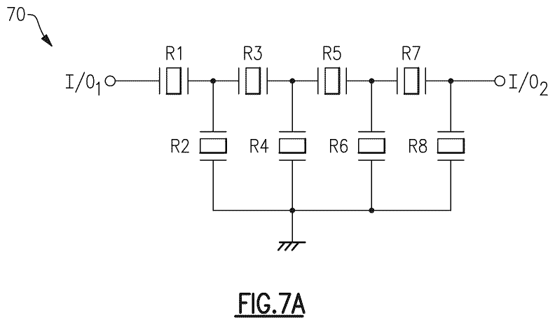

Though the structures of the IDT electrodes disclosed herein are described using a dual layer IDT electrode structure, any principles and advantages disclosed herein can be implemented with a single layer IDT, or any multilayer IDT structures. The rounded or reduced IDT electrode disclosed herein can be implemented together with other piston mode structures. For example, the rounded or reduced IDT electrode disclosed herein can have a hammer head shape that has a finger width at the edge region greater than a finger width at the center region, or a mini-bus bar. In some embodiments, the rounded or reduced IDT electrode disclosed herein can include dummy fingers that can function as pseudo-electrodes for mitigating or preventing interference with the propagation of a wave generated by the fingers of the IDT electrode. For example, FIGS. 6A, 6B, and 6C show an example of a surface acoustic wave (SAW) device that includes a mini-bus bar and dummy fingers.

FIG. 6A is a schematic top plan view of a surface acoustic wave (SAW) device 2 according to an embodiment. FIGS. 6B and 6C are schematic cross-sectional side views of the SAW device 2 of FIG. 6A taken along different locations. The SAW device 2 can include a support substrate 10, a piezoelectric layer 12, an intermediate layer 13 between the support substrate 10 and the piezoelectric layer 12, and an interdigital transducer (IDT) electrode 14 formed with the piezoelectric layer 12. In the illustrated embodiment, the IDT electrode 14 is formed over the piezoelectric layer 12. The SAW device 1 shown in FIG. 1A-1E is a multilayer piezoelectric substrata (MPS) SAW device. However, the principles and advantages disclosed herein may be implemented in any SAW device, such as, a temperature compensated surface acoustic wave (TC-SAW) device. The SAW device 2 shown in FIGS. 6A-6C can be generally similar to the SAW device 1 of FIGS. 1A-1E, except the SAW device 2 includes dummy fingers 50. Unless otherwise noted, the components of the SAW device 2 shown in FIGS. 6A-6C may be structurally and/or functionally the same as or generally similar to like components of the SAW device 1 of FIGS. 1A-1E.

The IDT electrode 14 can include a first layer 16 and a second layer 18. The IDT electrode 12 includes first bus bar 20, a second bus bar 22, a first set of fingers 24 that extends from the first bus bar, and a second set of fingers 26 that extends from the second bus bar. The IDT electrode 14 can include a first gap region GR1 between the first set of fingers 24 and the second bus bar 22, a second gap region GR2 between the second set of fingers 26 and the first bus bar 20, and an active region AR between the first and second gap regions GR1, GR2. In some embodiments, the IDT electrode 14 can include a first mini-bus bar 30 in the second gap region GR2 and a second mini-bus bar 32 in the first gap region GR1. The active region AR includes a center region CR, a first border region BR1 between the center region CR and the first gap region GR1, and a second border region BR2 between the center region CR and the second gap region GR2. The first and second border regions BR1, BR2 can be regions within 0.5 L, 1 L, or 1.5 L of the first and second sets of fingers 24, 26 from respective edges of the first and second sets of fingers 24, 26 or from the respective first or second gap regions GR1, GR2.

The dummy fingers 50 can extend from the first and second mini-bus bars 30, 32 and be positioned in the first and second gap regions GR1, GR2. The dummy fingers 50 are shorter than the fingers of the interdigital transducer electrode 12. The dummy fingers 50 can function as pseudo-electrodes for mitigating or preventing interference with the propagation of a wave generated by the fingers of the interdigital transducer electrode 12. The dummy fingers 50 of the interdigital transducer electrode 12 in the acoustic wave device 2 can have narrower widths in the first and second gap regions GR1, GR2 as compared to the fingers in the center region CR. In some embodiments, the narrower dummy fingers 50 in the edge region Re as compared to the fingers in the center region CR can improve the quality factor Q.

Any suitable principles and advantages disclosed herein can be implemented in a variety of acoustic devices. For example, any suitable principles and advantages disclosed herein can be applied to multilayer piezoelectric surface acoustic wave devices, non-temperature compensated surface acoustic wave devices that does not include a temperature compensation layer over an interdigital transducer electrode, Lamb wave resonators, shear horizontal mode acoustic wave device, or any acoustic wave devices that include an interdigital transducer electrode over a piezoelectric layer.

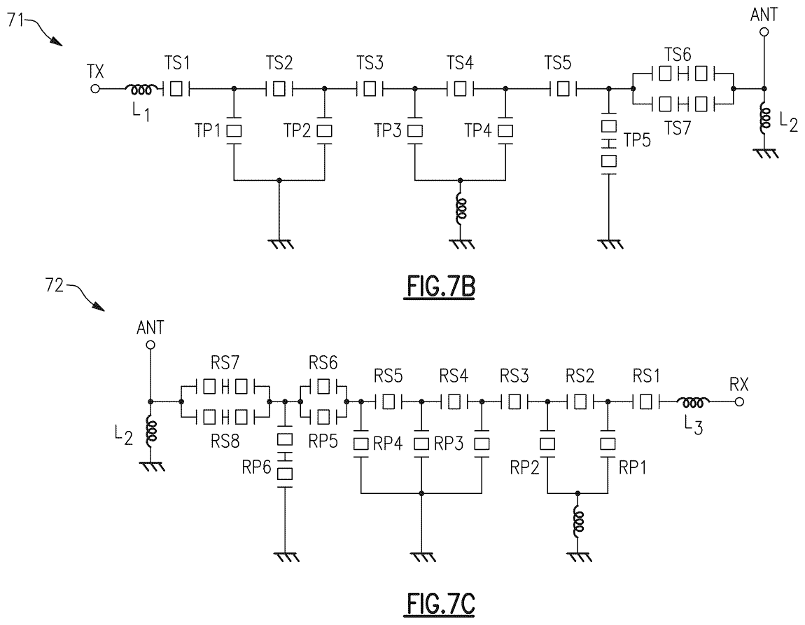

FIG. 7A is a schematic diagram of a ladder filter 70 that includes an acoustic wave resonator according to an embodiment. The ladder filter 70 is an example topology that can implement a band pass filter formed from acoustic wave resonators. In a band pass filter with a ladder filter topology, the shunt resonators can have lower resonant frequencies than the series resonators. The ladder filter 70 can be arranged to filter a radio frequency signal. As illustrated, the ladder filter 70 includes series acoustic wave resonators R1, R3, R5, and R7 and shunt acoustic wave resonators R2, R4, R6, and R8 coupled between a first input/output port I/O₁ and a second input/output port I/O₂. Any suitable number of series acoustic wave resonators can be in included in a ladder filter. Any suitable number of shunt acoustic wave resonators can be included in a ladder filter. The first input/output port I/O₁ can a transmit port and the second input/output port I/O₂ can be an antenna port. Alternatively, first input/output port I/O₁ can be a receive port and the second input/output port I/O₂ can be an antenna port.

FIG. 7B is a schematic diagram of an example transmit filter 71 that includes surface acoustic wave resonators of a surface acoustic wave component according to an embodiment. The transmit filter 71 can be a band pass filter. The illustrated transmit filter 71 is arranged to filter a radio frequency signal received at a transmit port TX and provide a filtered output signal to an antenna port ANT. The transmit filter 71 includes series SAW resonators TS1, TS2, TS3, TS4, TS5, TS6, and TS7, shunt SAW resonators TP1, TP2, TP3, TP4, and TP5, series input inductor L1, and shunt inductor L2. Some or all of the SAW resonators TS1, TS2, TS3, TS4, TS5, TS6, and TS7 and/or TP1, TP2, TP3, TP4, and TP5 can be a SAW resonators with a conductive strip for transverse mode suppression in accordance with any suitable principles and advantages disclosed herein. For instance, one or more of the SAW resonators of the transmit filter 71 can be any surface acoustic wave resonator disclosed herein. Any suitable number of series SAW resonators and shunt SAW resonators can be included in a transmit filter 71.

FIG. 7C is a schematic diagram of a receive filter 72 that includes surface acoustic wave resonators of a surface acoustic wave component according to an embodiment. The receive filter 72 can be a band pass filter. The illustrated receive filter 72 is arranged to filter a radio frequency signal received at an antenna port ANT and provide a filtered output signal to a receive port RX. The receive filter 72 includes series SAW resonators RS1, RS2, RS3, RS4, RS5, RS6, RS7, and RS7, shunt SAW resonators RP1, RP2, RP3, RP4, and RP5, and RP6, shunt inductor L2, and series output inductor L3. Some or all of the SAW resonators RS1, RS2, RS3, RS4, RS5, RS6, RS7, and RS8 and/or RP1, RP2, RP3, RP4, RP5, and RP6 can be SAW resonators with a conductive strip for transverse mode suppression in accordance with any suitable principles and advantages disclosed herein. For instance, one or more of the SAW resonators of the receive filter 72 can be any surface acoustic wave resonator disclosed herein. Any suitable number of series SAW resonators and shunt SAW resonators can be included in a receive filter 72.

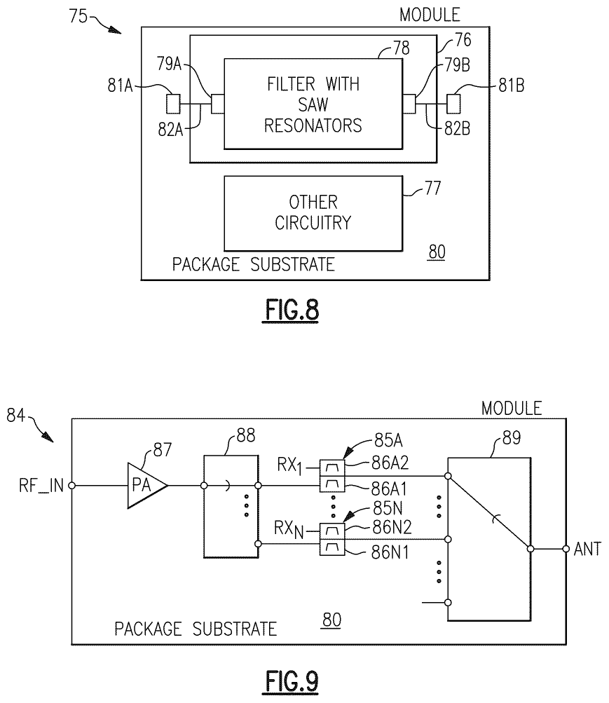

FIG. 8 is a schematic diagram of a radio frequency module 75 that includes a surface acoustic wave component 76 according to an embodiment. The illustrated radio frequency module 75 includes the SAW component 76 and other circuitry 77. The SAW component 76 can include one or more SAW resonators with any suitable combination of features of the SAW resonators and/or acoustic wave devices disclosed herein. The SAW component 76 can include a SAW die that includes SAW resonators.

The SAW component 76 shown in FIG. 8 includes a filter 78 and terminals 79A and 79B. The filter 78 includes SAW resonators. One or more of the SAW resonators can be implemented in accordance with any suitable principles and advantages of any surface acoustic wave resonator disclosed herein. The filter 78 can be a TC-SAW filter arranged as a band pass filter to filter radio frequency signals with frequencies below about 3.5 GHz in certain applications. The terminals 79A and 78B can serve, for example, as an input contact and an output contact. The SAW component 76 and the other circuitry 77 are on a common packaging substrate 80 in FIG. 8. The packaging substrate 80 can be a laminate substrate. The terminals 79A and 79B can be electrically connected to contacts 81A and 81B, respectively, on the packaging substrate 80 by way of electrical connectors 82A and 82B, respectively. The electrical connectors 82A and 82B can be bumps or wire bonds, for example. The other circuitry 77 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 75 can include one or more packaging structures to, for example, provide protection and/or facilitate easier handling of the radio frequency module 75. Such a packaging structure can include an overmold structure formed over the packaging substrate 80. The overmold structure can encapsulate some or all of the components of the radio frequency module 75.

FIG. 9 is a schematic diagram of a radio frequency module 84 that includes a surface acoustic wave component according to an embodiment. As illustrated, the radio frequency module 84 includes duplexers 85A to 85N that include respective transmit filters 86A1 to 86N1 and respective receive filters 86A2 to 86N2, a power amplifier 87, a select switch 88, and an antenna switch 89. The radio frequency module 84 can include a package that encloses the illustrated elements. The illustrated elements can be disposed on a common packaging substrate 80. The packaging substrate can be a laminate substrate, for example.

The duplexers 85A to 85N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 86A1 to 86N1 can include one or more SAW resonators in accordance with any suitable principles and advantages disclosed herein. Similarly, one or more of the receive filters 86A2 to 86N2 can include one or more SAW resonators in accordance with any suitable principles and advantages disclosed herein. Although FIG. 9 illustrates duplexers, any suitable principles and advantages disclosed herein can be implemented in other multiplexers (e.g., quadplexers, hexaplexers, octoplexers, etc.) and/or in switch-plexers.

The power amplifier 87 can amplify a radio frequency signal. The illustrated switch 88 is a multi-throw radio frequency switch. The switch 88 can electrically couple an output of the power amplifier 87 to a selected transmit filter of the transmit filters 86A1 to 86N1. In some instances, the switch 88 can electrically connect the output of the power amplifier 87 to more than one of the transmit filters 86A1 to 86N1. The antenna switch 89 can selectively couple a signal from one or more of the duplexers 85A to 85N to an antenna port ANT. The duplexers 85A to 85N can be associated with different frequency bands and/or different modes of operation (e.g., different power modes, different signaling modes, etc.).

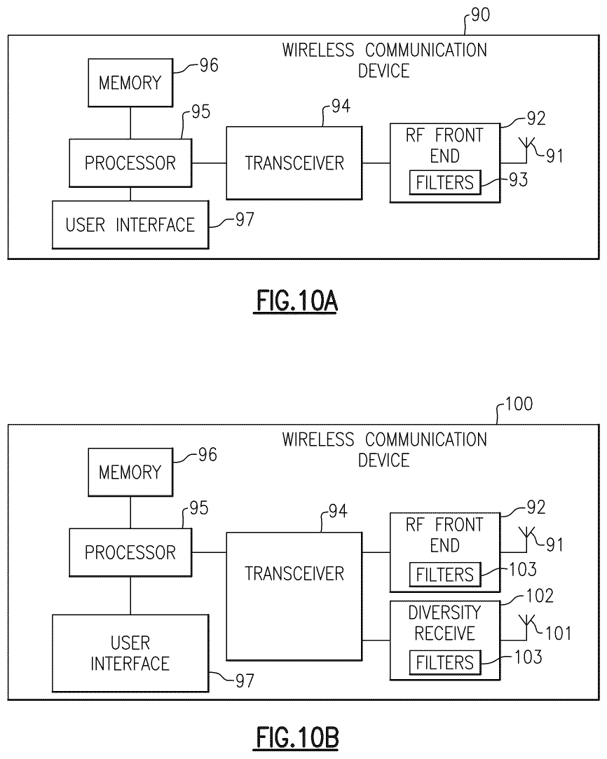

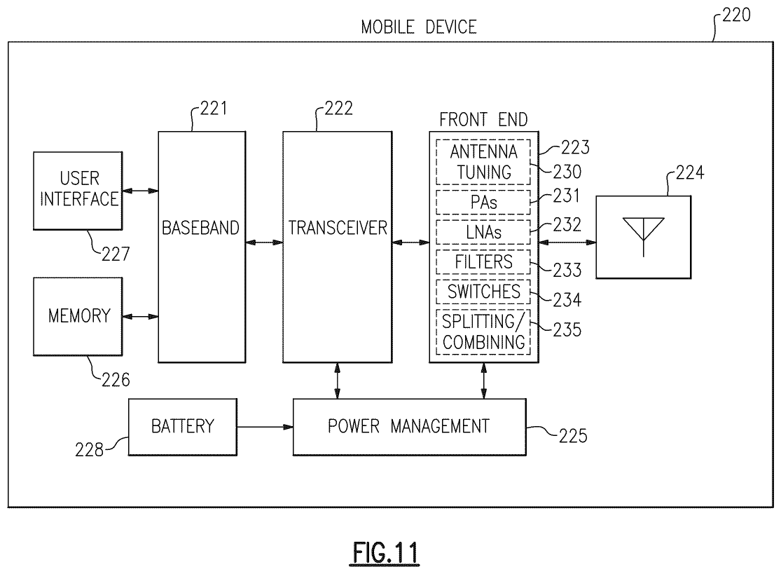

FIG. 10A is a schematic diagram of a wireless communication device 90 that includes filters 93 in a radio frequency front end 92 according to an embodiment. The filters 93 can include one or more SAW resonators in accordance with any suitable principles and advantages discussed herein. The wireless communication device 90 can be any suitable wireless communication device. For instance, a wireless communication device 90 can be a mobile phone, such as a smart phone. As illustrated, the wireless communication device 90 includes an antenna 91, an RF front end 92, a transceiver 94, a processor 95, a memory 96, and a user interface 97. The antenna 91 can transmit RF signals provided by the RF front end 92. Such RF signals can include carrier aggregation signals. Although not illustrated, the wireless communication device 90 can include a microphone and a speaker in certain applications.

The RF front end 92 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 92 can transmit and receive RF signals associated with any suitable communication standards. The filters 93 can include SAW resonators of a SAW component that includes any suitable combination of features discussed with reference to any embodiments discussed above.

The transceiver 94 can provide RF signals to the RF front end 92 for amplification and/or other processing. The transceiver 94 can also process an RF signal provided by a low noise amplifier of the RF front end 92. The transceiver 94 is in communication with the processor 95. The processor 95 can be a baseband processor. The processor 95 can provide any suitable base band processing functions for the wireless communication device 90. The memory 96 can be accessed by the processor 95. The memory 96 can store any suitable data for the wireless communication device 90. The user interface 97 can be any suitable user interface, such as a display with touch screen capabilities.

FIG. 10B is a schematic diagram of a wireless communication device 100 that includes filters 93 in a radio frequency front end 92 and a second filter 103 in a diversity receive module 102. The wireless communication device 100 is like the wireless communication device 90 of FIG. 10A, except that the wireless communication device 100 also includes diversity receive features. As illustrated in FIG. 10B, the wireless communication device 100 includes a diversity antenna 101, a diversity module 102 configured to process signals received by the diversity antenna 101 and including filters 103, and a transceiver 104 in communication with both the radio frequency front end 92 and the diversity receive module 102. The filters 103 can include one or more SAW resonators that include any suitable combination of features discussed with reference to any embodiments discussed above.

FIG. 11 is a schematic block diagram of a wireless communication device 220 that includes a filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 11 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of bulk acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 11, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 11, the power management system 225 receives a battery voltage from the battery 228. The battery 228 can be any suitable battery for use in the wireless communication device 220, including, for example, a lithium-ion battery.

Any suitable principles and advantages of the surface acoustic wave devices disclosed herein can be implemented with one or more temperature compensated SAW resonators. Temperature compensated SAW resonators include a temperature compensation layer (e.g., a silicon dioxide layer) over an interdigital transducer electrode to bring a temperature coefficient of frequency closer to zero.

Packaged surface acoustic wave devices disclosed herein can include one or more surface acoustic wave resonators included in a filter arranged to filter a radio frequency signal in a fourth generation (4G) Long Term Evolution (LTE) operating band. Packaged surface acoustic wave devices disclosed herein can include one or more surface acoustic wave resonators included in a filter arranged to filter a radio frequency signal in a fifth generation (5G) New Radio (NR) operating band within Frequency Range 1 (FR1). FR1 can be from 410 megahertz (MHz) to 7.125 gigahertz (GHz), for example, as specified in a current 5G NR specification. Packaged surface acoustic wave devices disclosed herein can include one or more surface acoustic wave resonators included in a filter with a passband corresponding to both a 4G LTE operating band and a 5G NR operating band within FR1.

Any of the embodiments disclosed herein can combined. Any of the embodiments described above can be implemented in association with a radio frequency system and/or mobile devices such as cellular handsets. The principles and advantages of the embodiments can be used for any systems or apparatus that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz, a frequency range from about 450 MHz to 2.5 GHz, or a frequency range from about 450 MHz to 3 GHz.

Aspects of this disclosure can be implemented in various electronic devices. Examples of the electronic devices can include, but are not limited to, consumer electronic products, parts of the consumer electronic products such as semiconductor die and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, a peripheral device, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of forming an acoustic wave device, the method comprising:
providing a piezoelectric layer;
forming an interdigital transducer electrode with the piezoelectric layer, the interdigital transducer electrode including a finger extending from a bus bar, the finger having a first region and a second region between the first region and the bus bar, the finger having a lower side, an upper side opposite the lower side, a sidewall between the lower side and the upper side, and a corner between the upper side and the sidewall; and
selectively removing at least a portion of the second region of the finger such that the corner in the second region of the finger has a more rounded corner than the corner in the first region.

2. The method of claim 1 wherein selectively removing includes ashing.

3. The method of claim 1 wherein selectively removing includes ion beam trimming.

4. The method of claim 1 wherein selectively removing includes dry etching.

5. The method of claim 1 wherein selectively removing includes wet etching.

6. The acoustic wave device of claim 1 a corner radius is in a range of 0.03 L to 0.07 L where L is a wavelength generated by the acoustic wave device.

7. The acoustic wave device of claim 1 wherein the corner in the second region has a corner radius in a range of 120 nm to 200 nm.

8. The acoustic wave device of claim 1 wherein selectively removing includes removing an edge from the corner in the second region.

9. The acoustic wave device of claim 1 wherein selectively removing includes narrowing a width of the upper side in the second region while maintaining a width of the lower side in the second region.

10. The method of claim 1 wherein the interdigital transducer electrode is formed on the piezoelectric layer.

11. The acoustic wave device of claim 1 wherein the interdigital transducer electrode further includes a second bus bar and dummy fingers in a gap region between the bus bar and fingers that extend from the second bus bar.

12. A method of forming an acoustic wave device, the method comprising:
providing a piezoelectric layer;
forming an interdigital transducer electrode with the piezoelectric layer, the interdigital transducer electrode including a finger extending from a bus bar, the finger having a first region and a second region between the first region and the bus bar, the finger having a lower side, an upper side opposite the lower side, a sidewall between the lower side and the upper side, and a corner between the upper side and the sidewall; and
selectively removing at least a portion of the second region of the finger such that a width of the upper side in the first region of the finger is greater than a width of the upper side in the second region of the finger.

13. The method of claim 12 wherein selectively removing includes ashing.

14. The method of claim 12 wherein selectively removing includes ion beam trimming.

15. The method of claim 12 wherein selectively removing includes etching.

16. The method of claim 12 wherein a width of the lower side in the first region is greater than the width of the upper side in the second region.

17. The method of claim 16 wherein a difference between the widths of the lower side and the upper side in the second region is in a range of 0.06 L to 0.1 L where L is a wavelength generated by the acoustic wave device.

18. The method of claim 12 wherein a difference between the width of the upper side in the first region and the width of the upper side in the second region is in a range of 0.06 L to 0.1 L where L is a wavelength generated by the acoustic wave device.

19. The method of claim 12 wherein a difference between the width of the upper side in the first region and the width of the upper side in the second region is in a range of 80 nm to 800 nm.

20. The method of claim 12 wherein selectively removing includes narrowing a width of the upper side in the second region while maintaining a width of the lower side in the second region.
